(19) United States
(12) Patent Application Publication
(10) Pub. No.: US 2007/0001263 A1
(43) Pub. Date: Jan. 4, 2007

(54) Semiconductor device

(75) Inventor: Akio Nakagawa, Chigasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/477,651

(22) Filed: Jun. 30, 2006

(30) Foreign Application Priority Data
Jul. 1, 2005 (JP) 2005-193398
Jun. 29, 2006 (JP) 2006-180093

(51) Int. Cl. H01L 27/082

(52) U.S. Cl. 257/565

(57) ABSTRACT

A semiconductor device comprises a first semiconductor layer of the first conduction type; and a second semiconductor layer of the second conduction type formed on one surface of the first semiconductor layer. The semiconductor device also comprises a gate electrode formed in a trench with an insulator interposed therebetween, the trench passing through the second semiconductor layer and reaching the first semiconductor layer; and a third semiconductor layer of the first conduction type formed on a surface of the second semiconductor layer between adjacent gate electrodes. The semiconductor device further comprises a first main electrode connected to the second and third semiconductor layers: a fourth semiconductor layer of the second conduction type formed on the other surface of the first semiconductor layer; and a second main electrode connected to the fourth semiconductor layer. The semiconductor layer between adjacent gates has a width d, which satisfies a relation of 2λ≦d≦0.3 μm (λ: a thickness of a channel).

### CROSS REFERENCE TO RELATED APPLICATION

This application is based on and claims the benefit of priority from prior Japanese Patent Applications No. 2005-193398, filed on Jul. 1, 2005, and No. 2006-180093, filed on Jun. 29, 2006, the entire contents of which are incorporated herein by reference.

### BACKGROUND OF THE INVENTION

1. Field of the Invention

The present invention relates to a power semiconductor device such as an IGBT (Insulated Gate Bipolar Transistor), and more particularly to a semiconductor device having a trench gate structure.

2. Description of the Related Art

The IGBT has been known as a power semiconductor element, which has a high-speed switching performance of a MOSFET together with a low on-resistance performance of a bipolar transistor and can suppress the loss even with a high breakdown voltage over 600 V.

It is important for such the IGBT to reduce the on-voltage in what way. For example. JP-A 2002-43573 (paragraph 0018, FIG. 1) discloses an IGBT having a lowered on-state voltage. The on-state voltage is lowered by forming roughness on an interface between an n⁻-type base layer and a p⁺-type emitter layer to increase the area of the interface and enhancing the efficiency of injection of holes from the p⁺-type emitter layer into the n⁻-type base layer. The increase in the area of the interface between the n⁻-type base layer and the p⁺-type emitter layer has a limit of reduction in the on-state voltage.

JP-A 11-274484 (paragraphs 0069-0070, FIG. 1) discloses an IGBT having an on-state voltage reduced by patterning the interval between trenches as fine as 1.5 μm or below.

### SUMMARY OF THE INVENTION

In an aspect the present invention provides a semiconductor device, comprising: a first semiconductor layer of the first conduction type: a second semiconductor layer of the second conduction type formed on one surface of the first semiconductor layer; a gate electrode formed in a trench with an insulator interposed therebetween, the trench passing through the second semiconductor layer and reaching the first semiconductor layer: a third semiconductor layer of the first conduction type formed on a surface of the second semiconductor layer between adjacent gate electrodes; a first main electrode connected to the second and third semiconductor layers: a fourth semiconductor layer of the second conduction type formed on the other surface of the first semiconductor layer; and a second main electrode connected to the fourth semiconductor layer. In this case, the semiconductor layer between adjacent gates has a width d ranging from 0.55 nm to 0.3 μm.

In another aspect the present invention provides a semiconductor device, comprising: a first semiconductor layer of the first conduction type; a second semiconductor layer of the second conduction type formed on one surface of the first semiconductor layer: a gate electrode formed in a trench with an insulator interposed therebetween, the trench passing through the second semiconductor layer and reaching the first semiconductor layer; a third semiconductor layer of the first conduction type formed on the a surface of the second semiconductor layer between adjacent gate electrodes: a first main electrode connected to the second and third semiconductor layers; a fourth semiconductor layer of the second conduction type formed on the other surface of the first semiconductor layer; and a second main electrode connected to the fourth semiconductor layer. In this case, the semiconductor layer between adjacent gates has a width d, which satisfies the following relation:
0.55 nm≦d≦0.1·L·S/W+2λ
where L denotes a depth from an interface between the first semiconductor layer and the second semiconductor layer to the bottom of the trench; S an element repetition pitch; W a thickness of the first semiconductor layer; and λ a thickness of a channel.

In yet another aspect the present invention provides a semiconductor device, comprising: a first semiconductor layer of the first conduction type; a second semiconductor layer of the second conduction type formed on one surface of the first semiconductor layer: a gate electrode formed in a trench with an insulator interposed therebetween, the trench passing through the second semiconductor layer and reaching the first semiconductor layer; a third semiconductor layer of the first conduction type formed on a surface of the second semiconductor layer between adjacent gate electrodes; a first main electrode connected to the second and third semiconductor layers; a fourth semiconductor layer of the second conduction type formed on the other surface of the first semiconductor layer; and a second main electrode connected to the fourth semiconductor layer, wherein the semiconductor layer between adjacent gates has a width d, which satisfies a relation of 2λ≦d≦0.3 μm (λ: a thickness of a channel).

### BRIEF DESCRIPTION OF THE DRAWINGS

FIG. 1 is a plan view of an IGBT according to a first embodiment of the present invention:

FIG. 2 is a cross-sectional view taken along A-A′ of FIG. 1;

FIG. 3 is a graph illustrative of a relation between a carrier concentration and a distance along the thickness of an n⁻-type base layer in the IGBT;

FIG. 4 is a graph illustrative of a relation between an electron concentration and a distance in a mesa section from a gate oxide in the IGBT;

FIG. 5 is a graph illustrative of a relation between a channel resistance and a width of a mesa section in the IGBT:

FIG. 6 is a graph illustrative of a relation between a voltage drop and a width of a mesa section in the IGBT;

FIG. 7 is a cross-sectional view illustrative of various dimensional parameters of the IGBT;

FIG. 8 shows turn-off waveforms when the mesa section is made 20 nm;

FIG. 9 is a cross-sectional view illustrative of the IGBT of FIG. 1 in order of process step;

FIG. 10 is a cross-sectional view illustrative of the IGBT of FIG. 1 in order of process step;

FIG. 11 is a cross-sectional view illustrative of the IGBT of FIG. 1 in order of process step;

FIG. 12 is a cross-sectional view illustrative of the IGBT of FIG. 1 in order of process step:

FIG. 13 is a cross-sectional view illustrative of the IGBT of FIG. 1 in order of process step;

FIG. 14 is a cross-sectional view illustrative of the IGBT of FIG. 1 in order of process step;

FIG. 15 is a cross-sectional view illustrative of the IGBT of FIG. 1 in order of process step;

FIG. 16 is a cross-sectional view illustrative of the IGBT of FIG. 1 in order of process step;

FIG. 17 is a cross-sectional view illustrative of the IGBT of FIG. 1 in order of process step;

FIG. 18 is a cross-sectional view illustrative of the IGBT of FIG. 1 in order of process step;

FIG. 19 is a cross-sectional view illustrative of the IGBT of FIG. 1 in order of process step; and

FIG. 20 is a cross-sectional view illustrative of an IGBT of the conventional art.

### DETAILED DESCRIPTION OF THE INVENTION

Embodiments of the present invention will now be described below with reference to the drawings.

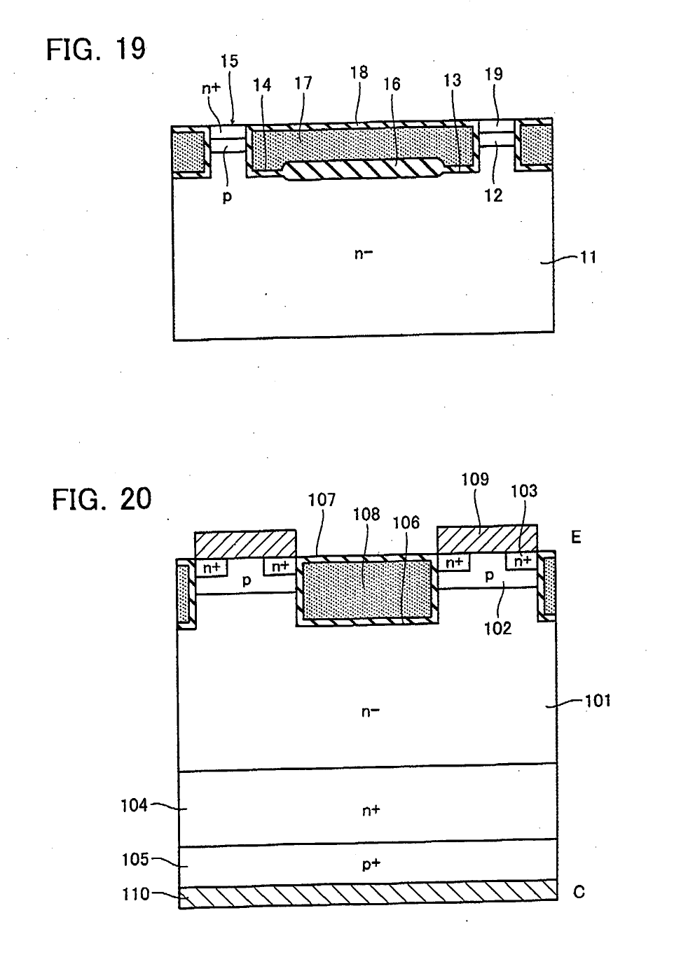

FIG. 20 is across-sectional view illustrative of a general vertical IGBT having a trench gate structure. A high-resistance, n⁻-type base layer 101 has one surface on which a p-type base layer 102 is formed. An n⁺-type source layer 103 is formed on the upper surface of the p-type base layer 102.

On the other surface of the n⁻-type base layer 101, an n⁺-type buffer layer 104 and a p⁺-type emitter layer 105 are formed in this order. In these semiconductor layers, a trench 6 is formed through the n⁺-type source layer 103 and the p-type base layer 102 to the n⁻-type base layer 101. A gate electrode 108 composed of polysilicon is buried in the trench 6 with a gate oxide 107 interposed therebetween. An emitter electrode 109 is formed on the p-type base layer 102 and the n⁺-type source layer 103. A collector electrode 110 is formed on the lower surface of the p⁺-type emitter layer.

In the IGBT thus configured, the emitter electrode 109 is grounded and the collector electrode 110 is supplied with a positive voltage. In this state, when the gate electrode is supplied with a positive voltage the side of the p-type base layer 102 opposing the gate electrode 108 is inverted to form a channel. In this case, the positive voltage is higher than a threshold voltage of a MOS region, which includes the n⁺-type source layer 103, the p-type base layer 102, the n⁻-type base layer 101, the gate oxide 107 and the gate electrode 108. Thus, the majority carrier (electrons) flows from the n⁺-type source layer 103 through the channel into the n⁻-type base layer 101. In addition, drawn by the electrons, the minority carrier (holes) flows from the p⁺-type emitter layer 10S through the n⁺-type buffer layer 104 into the n⁻-type base layer 101. As a result, the high-resistance, n⁻-type base layer 101 is filled with a number of holes and electrons, and the resistance thereof is lowered by conductivity modulation such that a large current can flow.

### First Embodiment

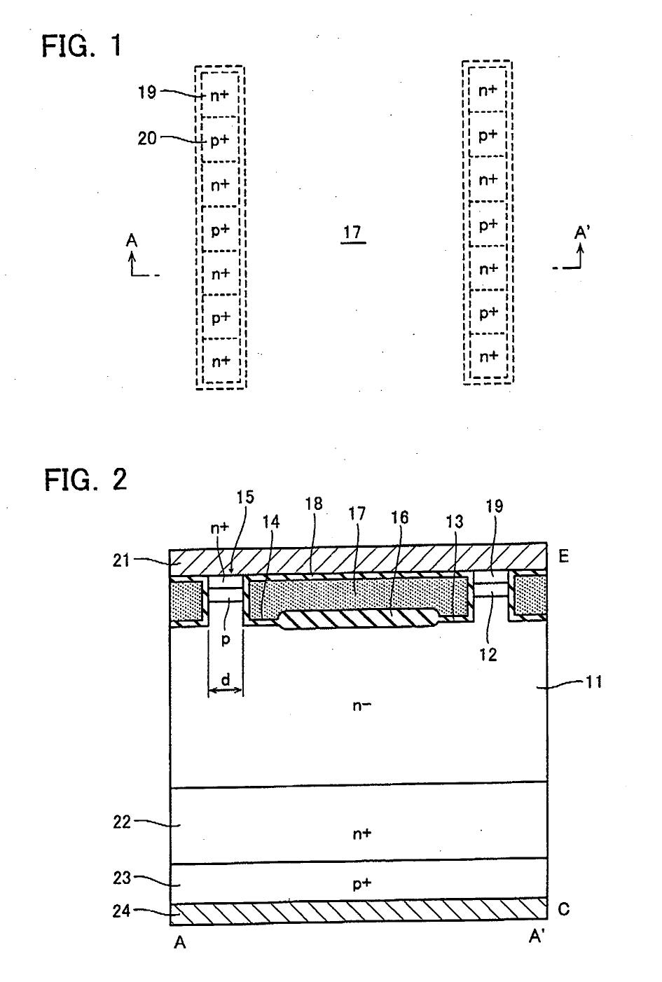

FIG. 1 is a plan view illustrative of the major part of an IGBT according to a first embodiment of the present invention, and FIG. 2 is a cross-sectional view taken along A-A′ of FIG. 1.

A high-resistance, n⁻-type base layer 11 has one surface on which a p-type base layer 12 is formed.

In these semiconductor layers, a trench 13 is formed through the p-type base layer 12 to the n⁻-type base layer 11. A gate electrode 17 composed of polysilicon is buried in the trench 13 with a gate oxide 14 interposed therebetween. A gate oxide 18 covers the upper portion of the gate electrode 17. An LOCOS (Local Oxidation of Silicon) oxide 16 is formed in a portion of the gate oxide 14 particularly located on the bottom of the trench 13 to reduce the capacitive coupling between the gate electrode 17 and the n⁻-type base layer 11. A silicon layer 15 (hereinafter referred to as a “mesa section”) formed between adjacent trenches 13 has a width d set at 0.1 μm, for example. On the upper surface of the p-type base layer 12 contained in the mesa section 15, as shown in FIG. 1, an n⁺-type source layer 19 and a p-type contact layer 20 are formed alternately in a direction orthogonal to the page of FIG. 2. The n⁺-type source layer 19 and the p-type contact layer 20 are connected to an emitter electrode 21 that covers these layers. On the other surface of the n⁻-type base layer 11, an n⁺-type buffer layer 22 and a p⁺-type emitter layer 23 are formed in this turn. The p⁺-type emitter layer 23 is connected to a collector electrode 24 that covers this layer.

The following description is given to operation of the IGBT thus configured according to this embodiment.

The emitter electrode 21 is grounded and the collector electrode 24 is supplied with a positive voltage. In this state, when the gate electrode 17 is supplied with a positive voltage, the side of the p-type base layer 12 opposing the gate electrode 17 is inverted to form a channel. Thus, the majority carrier (electrons) flows from the n⁺-type source layer 19 through the channel into the n⁻-type base layer 11. In addition, drawn by the electrons, the minority carrier (holes) flows from the p⁺-type emitter layer 23 through the n⁺-type buffer layer 22 into the n⁻-type base layer 11. As a result, the high-resistance, n⁻-type base layer 11 is filled with a number of holes and electrons, and the resistance thereof is lowered by conductivity modulation such that a large current can flow.

In general, the current flowing in the IGBT is a current composed of an electron current and a hole current, and an electron current density Jn and a hole current density Jp are represented as follows.
Jn=qnμnE+qDn∂n/∂x (Expression 1)
Jp=qnμpE+qDp∂p/∂x

q: Electron Mass,

n: Electron Concentration,

p: Hole Concentration,

μn: Electron Mobility,

μp: Hole Mobility,

Dn: Electron Diffusion Coefficient,

Dp: Hole Diffusion Coefficient, and

x: Distance along Thickness of the n-type base layer.

In the above expression, on the right side the first term denotes a drift current and the second term denotes a diffusion current. In the IGBT of the conventional art, among holes injected from the p⁺-type emitter layer 23 into the n⁻-type base layer 11, holes not recombined with electrons are released from the emitter electrode 21 through the p-type base layer 12. In the IGBT according to this embodiment, however, the width d of the mesa section 15 is made as extremely narrow as 0.1 μm. Therefore, channels formed along both sides of the p-type base layer 12 by adjacent gate electrodes 17 are joined to each other such that most of the p-type base layer 12 can behave like the high-concentration, n-type layer. As a result, holes can not pass through the mesa section 15 and the whole current flowing in the IGBT consists only of the electron current. The electron mobility μn is much larger than the hole mobility μp. Accordingly, when almost the whole current flowing in the IGBT consists of the electron current, an extremely low on-state voltage can be realized.

On the other hand, at the time of turn-off, the gate electrode 17 is supplied with a negative voltage to turn the whole silicon layer into a p-channel. This allows holes accumulated in the n⁻-type base layer 11 to be drawn without a hitch. Therefore, a narrowed width d of the mesa section 15 exerts no influence on the turn-off speed.

### Second Embodiment

The width d of the mesa section 15 is made 0.1 μm in the above embodiment though the width d is not limited to 0.1 μm.

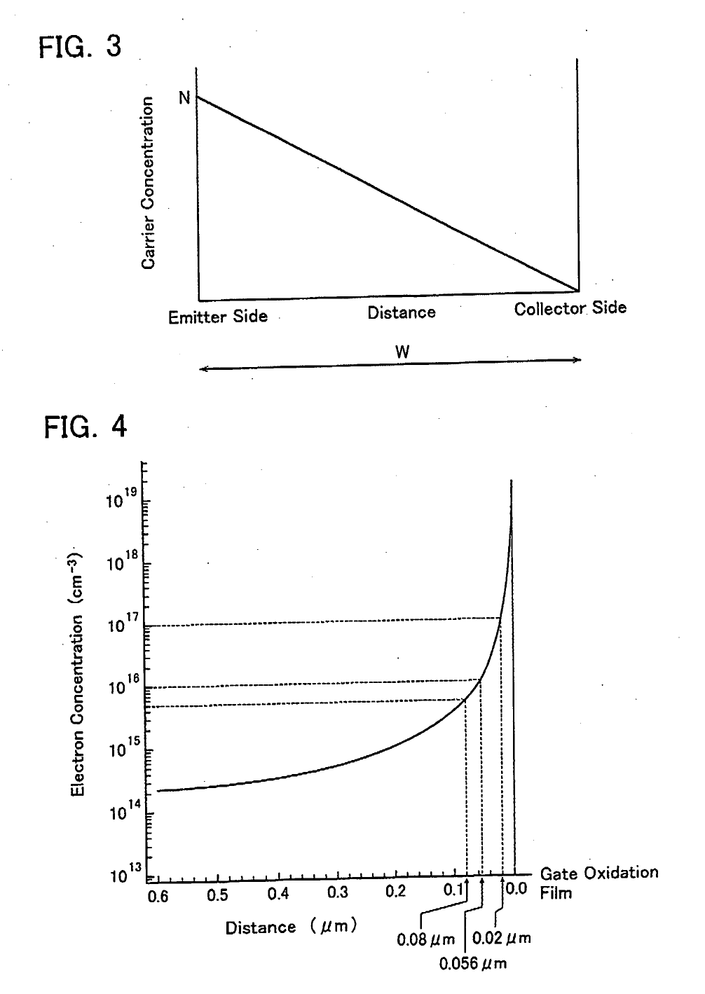

FIG. 3 shows a distribution of carrier (electron) concentrations across the n⁻-type base layer 11 from the emitter electrode 21 toward the collector electrode 24. As shown, the distribution of carrier concentrations is linear. When the whole current consists of the electron current, the hole current becomes zero because the diffusion current and the drift current cancel each other out. In contrast, as for the electron current, the diffusion current and the drift current flow in the same direction and have the same value. Therefore, the whole current is equal to double the diffusion current of electrons and the current density J can be represented by the following expression 2.
J=2qDn∂n/∂x=2qDnN/W (Expression 2)

N: Electron Concentration in the mesa section

W: Thickness of the n⁻-type base layer 11

Generally, in a 600V-series IGBT, the n⁻-type base layer 11 has a thickness W of 40 μm. A frequently used current density J is about 25 A/cm². Based on such the condition, the electron concentration N is derived from the expression 2 as follows:

$$\begin{matrix}N = JW / ( 2 qDn ) \\ = 25 \times 40 \times {10}^{- 4} / ( 2 \times 1200 \times 1.38 \times {10}^{- 23} \times 300 ) \\ \approx 1 \times {10}^{16} ( {cm}^{- 3} )\end{matrix} \qquad ( Expression 3 )$$

In the mesa section 15, electrons caused from the gate electrode 17 on one side can move in the channel by a distance. (that is, a thickness λ of the channel), which is defined by a Debye length λ1. The Debye length λ1 is derived from:
λ1=√(kε₀T/Nq²) (Expression 4)

k: Boltzmann Constant

ε₀: Silicon Permittivity

T; Electron Temperature

The electron concentration N in the mesa section 15 is equal to the sum of electron concentrations in the channels formed along both sides of the mesa section 15. Accordingly, substitution of half the electron concentration resulted from the expression 3, or N=0.5×10¹⁶ cm⁻³, into the expression 4 yields a Debye length λ1 of about 0.058 μm. Therefore, if the width d of the mesa section 15 is equal to or less than 0.058×2=0.116 μm, the entire of the mesa section 15 turns into a channel. From this viewpoint, 0.116 μm may become the upper limit.

### Third Embodiment

FIG. 4 is a graph illustrative of an electron concentration (cm⁻³) relative to a distance (μm) from the gate oxide 14 simulated with a device simulator. The channel thickness λ in the mesa section 15 may also be derived from the device simulation results. In this case, when the device simulation result is used on condition that the electron concentration in the mesa section 15 is equal to or more than 0.5×10¹⁶ cm⁻³, the value of the thickness of the channel was equal to 0.08 μm. Therefore, if the width d of the mesa section 15 is equal to or less than 0.08×2=0.16 μm, the entire of the mesa section 15 turns in a channel. From this viewpoint, 0.16 μm may become the upper limit.

### Fourth Embodiment

The width d of the mesa section 15 may also be derived from a theoretical expression for on-state voltage. When the whole current flowing in the IGBT consists of the electron current, a voltage drop (on-state voltage) V_{F} can be represented by the following expression 5.

$${V}_{F} = \frac{2 kT}{q} ln \{ \frac{1}{{n}_{i}} ( ( \sqrt{\frac{QJ}{{qD}_{n}}} + {p}_{c} ) exp ( \frac{{JW}_{i}}{Jqa} ) - {p}_{c} ) \} + {R}_{ch} J \qquad ( Expression 5 )$$

J: Current Density

q=1.6×10¹⁹, nᵢ=1.4×10¹⁰, Dₙ=μₑkT/q

a=3.24×10¹⁸ cm⁻¹sec⁻¹, P_{c}=9.39×10¹⁶ cm⁻³

Q: Dose into the p-emitter

μ_{c}: Electron Mobility of about 300 in the p-emitter

k=1.38×10⁻²³ J/K

Wᵢ: Thickness of the n-base

R_{ch}; Channel Resistance

The voltage drop V_{F} depends on the current density J and the channel resistance Rch. The current density J depends on the width d of the mesa section 15 as described earlier.

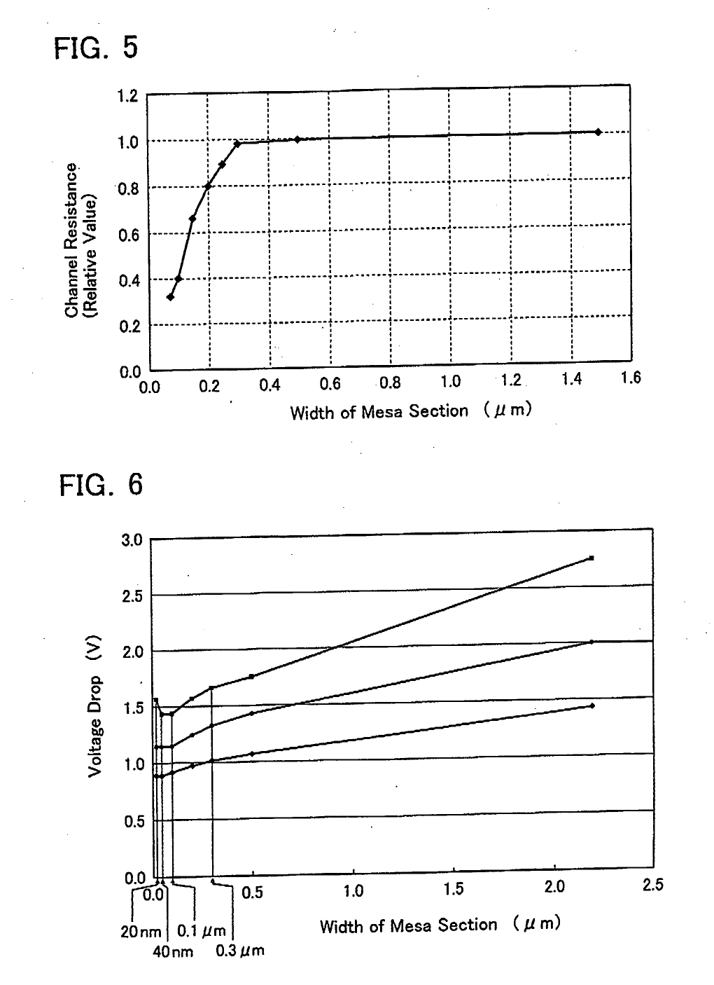

FIG. 5 shows a relation between a channel resistance (relative value) and the width d of the mesa section 15. When the width d of the mesa section 15 reduces below 0.3 μm, the channel resistance Rch sharply lowers. Accordingly, from the viewpoint of the reduction in the channel resistance in d, 0.3 μm may become the upper limit. This can be thought that the electric fields from adjacent gate electrodes 17 include field components orthogonal to the flow of electron current, which cancel each other out as both gate electrodes 17 are made closer to each other, resulting in a smooth flow of electron current.

As described above, the voltage drop V_{F} depends on the width d of the mesa section 15.

FIG. 6 is a graph illustrative of a relation between a voltage drop and the width d of the mesa section 15, resulted from the device simulator. Three curves show respective properties when the current density is 200 A/cm², 700 A/cm², and 1700 A/cm² from below. As obvious from this figure, when the width d of the mesa section 15 reduces below 0.3 μm, the on-resistance sharply lowers (the gradient of the graph increases). It can be thought that the channel resistance property described earlier also exerts a large influence. Therefore, the width d of the mesa section 15 may become the upper limit at 0.3 μm. If the width d is less than 0.1 μm, the on-state voltage is made flat to stabilize the property. Accordingly, 0.1 μm may become the upper limit of the width d of the mesa section 15 within a preferred range.

On the other hand, as the lower limit of the mesa section 15, a limit of roughness (0.55 nm=the dimension of an atom) is cited first. Namely, as the channel resistance Rch is susceptive to scattering due to roughness of the gate oxide 14, an excessively thinned width may increase the resistance in reverse. Accordingly, the lower limit of the width d becomes the dimension of roughness, 0.55 nm.

As can be seen from the graph of the relation between the width d of the mesa section 15 and the voltage drop shown in the figure, the voltage drop sharply increases on the curve of 1700 A/cm² when the width d of the mesa section 15 is narrowed from 40 nm to 20 nm. This can be thought to indicate that, on driving at a large current as 1700 A/cm², driving only with the electron current has a limit. Therefore, more preferably, in particular on large current driving or the like, the lower limit of the width d of the mesa section 15 is set at 30 nm or 40 nm, taking the mean between 40 nm and 20 nm.

As obvious also from the expression 5, the on-state voltage VF varies depending on the dose Q into the p⁺-type emitter layer 23. A smaller dose Q is better though 5×10¹² to 2×10¹⁴ [cm⁻³] may be suitable for ensuring injection of holes. If the n⁻-type buffer layer 22 is provided a dose Q of 5×10¹² to 2×10¹⁴ [cm⁻³] is appropriate.

### Fifth Embodiment

In the above embodiments, the mesa section 15 is entirely turned into a channel to cut off the hole passage such that the whole current can consist of the electron current. Accordingly to the simulation by the Inventor et al., if the hole current can be held below 10% of the whole current, the effect of the present invention can be obtained substantially as confirmed.

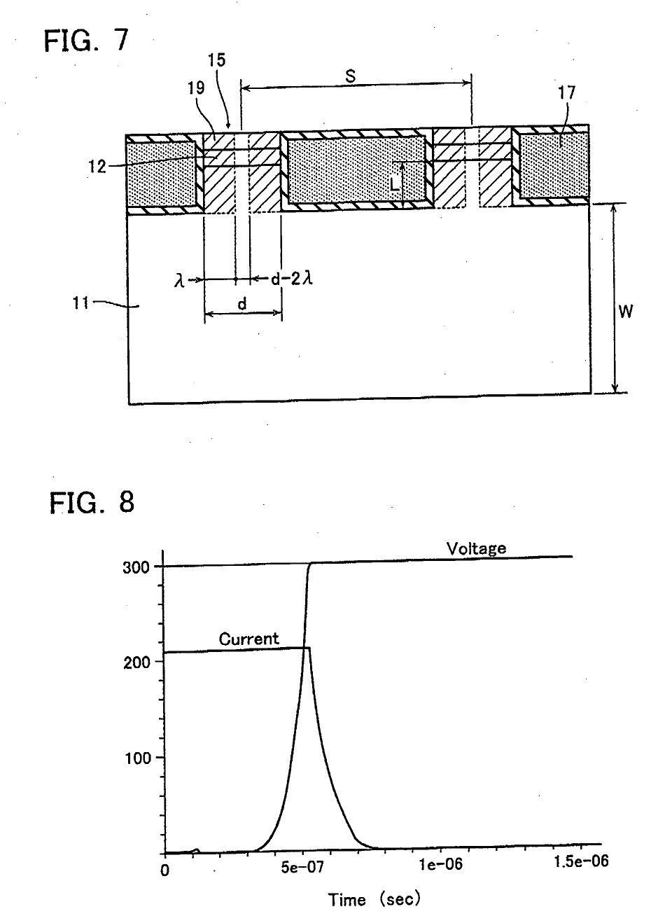

Therefore. FIG. 7 is referenced to derive the width d of the mesa section 15 that can retain the hole current below 10%. In this case, the hole current Jp flows by diffusion in a portion of (d−2λ), that is, the width d of the mesa section 15 minus the thickness 2λ of the channels along both sides. Accordingly, it is derived as follows.
Jp=qDpN(d−2λ)/L (Expression 6)

where Dp: Hole Diffusion Coefficient

λ: Channel Thickness

L: Distance from Trench Tip to the p-type base layer, which corresponds to Trench Depth.

A ratio of the hole current Jp to the whole current can be derived as the following expression 7.
Jp/SJ (Expression 7)

S: Element Repetition Pitch

The hole current Jp kept below 10% is required to satisfy the following condition.
Jp/SJ=(d−2λ)W/LS≦0.1 (Expression 8)
d≦0.1*LS/W+2λ

In this case, when the above-described Debye length is equal to λ1, for example, the channel thickness λ becomes λ1=0.041 at an electron concentration of 1×10¹⁶ cm³.

In addition, computation from the device simulator shown in FIG. 4 results in λ=0.056 at the electron concentration of 1×10¹⁶ cm⁻³.

### Sixth Embodiment

FIG. 8 shows turn-off waveforms in the IGBT when the width d of the mesa section 15 is set at 20 nm. The waveform falling from the left side to the right side is a current waveform while the waveform rising from the left side to the right side is a voltage waveform. In the IGBT of the conventional art, when the gate voltage lowers below the threshold of MOSFET, charges accumulated inside are discharged such that a current flows. To the contrary, as in the above embodiments, the width d of the mesa section 15 is made about 0.1 μm, even if the gate voltage lowers below the threshold both electrons and holes can not exist in the channel. Accordingly, a discharge current is not obtained and the voltage drop increases temporarily. In FIG. 8, the voltage drop slightly increases immediately after 0.1 μs for this reason. Thereafter, when the gate voltage is made negative to form a p-type channel in the semiconductor layer such that holes flow in the channel, the device turns off.

Such the temporary increase in voltage drop is not preferable though the resultant voltage loss is a small and negligible extent. It is preferable, however, that such the phenomenon is not present, if possible. In particular, when a load connected to the IGBT is short-circuited and a high voltage is applied to the n⁻-type base layer 11, a high electric field arises on the collector electrode 24 if no hole current flows. Accordingly, it is required to avoid this problem.

Therefore, the channel region requires a passage for continuous (or all times) flow of holes. Accordingly, when a high-voltage current flows in the IGBT, the width d of the mesa section 15 should be made double the Debye length λ or more (d≧2λ), for example, to form the passage for continuous flow of holes.

Even when a gate voltage of the threshold voltage is applied, the passage for continuous flow of holes may be formed in the channel region. In this case, it is required that the width d of the mesa section 15 is set double or more than the width Wx of a depletion layer formed under the threshold voltage (one side of the mesa section 15) (d≧2×Wx). Thus, the passage for continuous flow of holes can be formed in the channel region.

The width Wx of the depletion layer formed under the threshold voltage can be represented by the following expression.

$$Wx = \sqrt{\frac{4 ɛ kT ln ( {N}_{A} / {n}_{i} )}{{q}^{2} {N}_{A}}} \qquad ( Expression 9 )$$

where N_{A}: Acceptor Density

ni: Carrier Density of Intrinsic Semiconductor

ε: Permittivity

T: Electron Temperature

k=1.38×10⁻²³ J/K

In general, estimation of the acceptor density N_{A} at N_{A}4.5×10¹⁷ [cm⁼³], slightly larger than usual, results in Wx=about 0.05 μm. If the thickness d of the mesa section 15 is double this value, (0.05×2), or equal to 0.1 μm or more (d≧0.1), the passage for continuous flow of holes can be formed in the channel region. The threshold voltage can be controlled with the acceptor density N_{A}. Accordingly, when the width d of the mesa section 15 is made equal to 0.1 μm or more, the IGBT can be turned off only with the gate voltage lowered below the threshold voltage, that is, without applying a negative gate voltage.

A reduction in the channel resistance Rch requires d≦0.3 μm like in the above embodiments.

Therefore, it can be found that the IGBT having a reduced voltage drop due to the small channel resistance Rch and a property equivalent to that of the IGBT of the conventional art can be realized by setting:
0.1≦d≦0.3 μm or (Expression 10)
2λ≦d≦0.3 μm (Expression 11)

It is also possible to set the thickness d so as to satisfy both expressions.

### Embodiment of Manufacturing Method

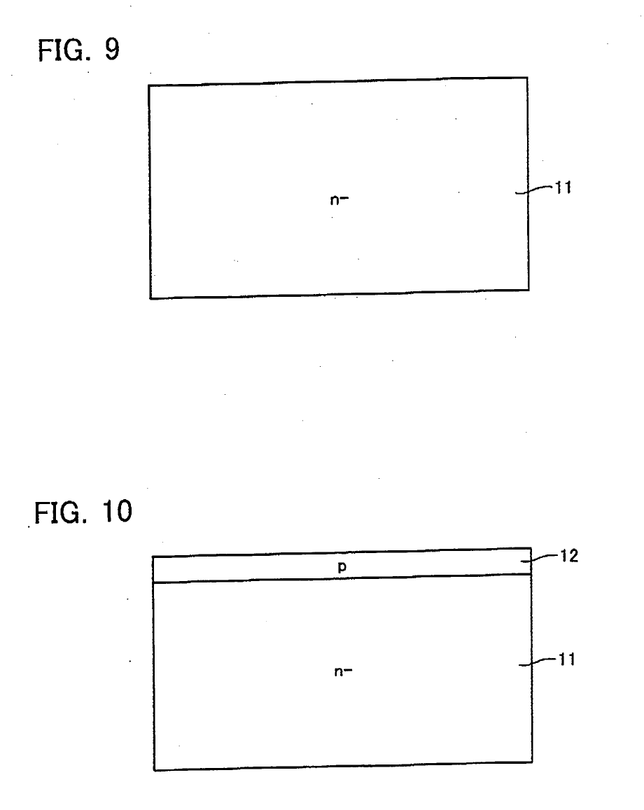

FIGS. 9-19 are referenced next to describe process steps of manufacturing the IGBT according to the above first embodiment.

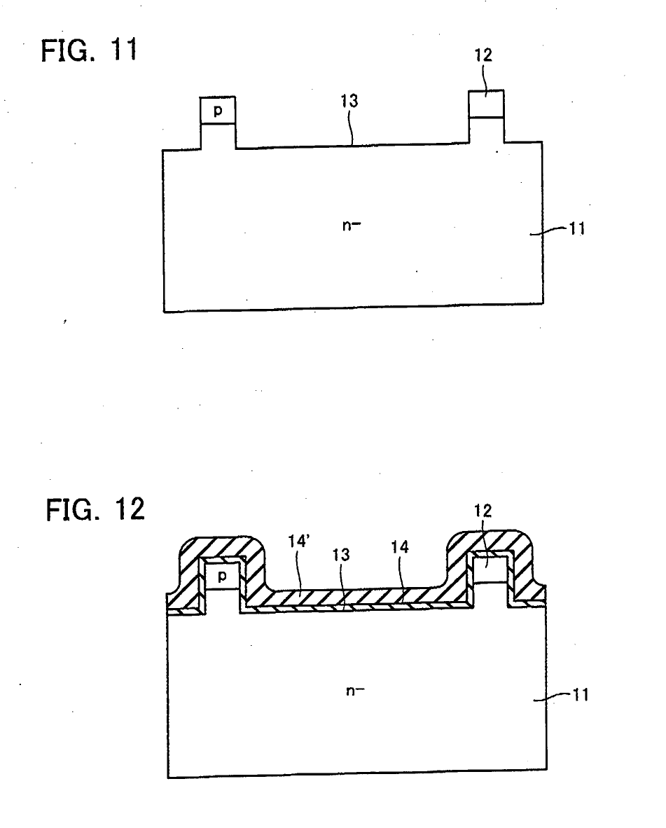

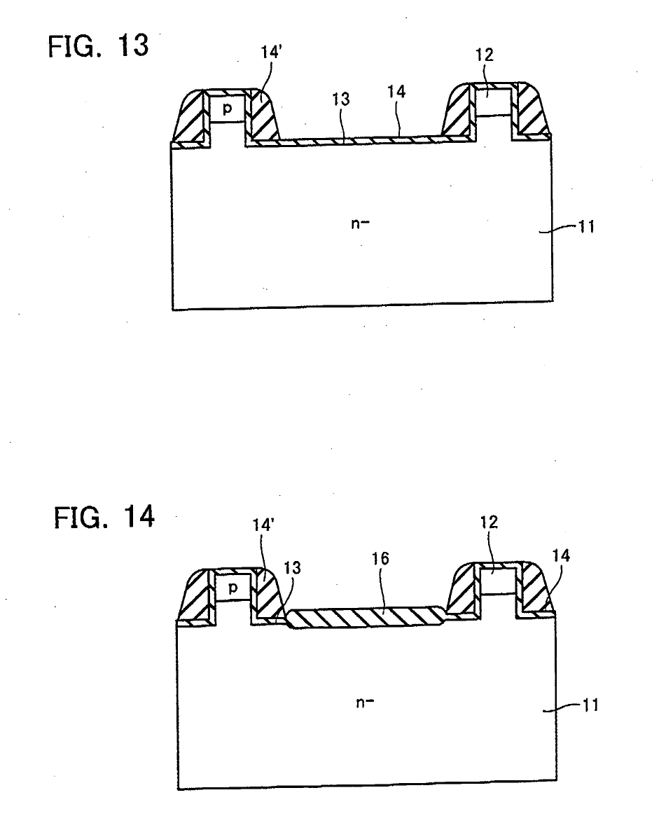

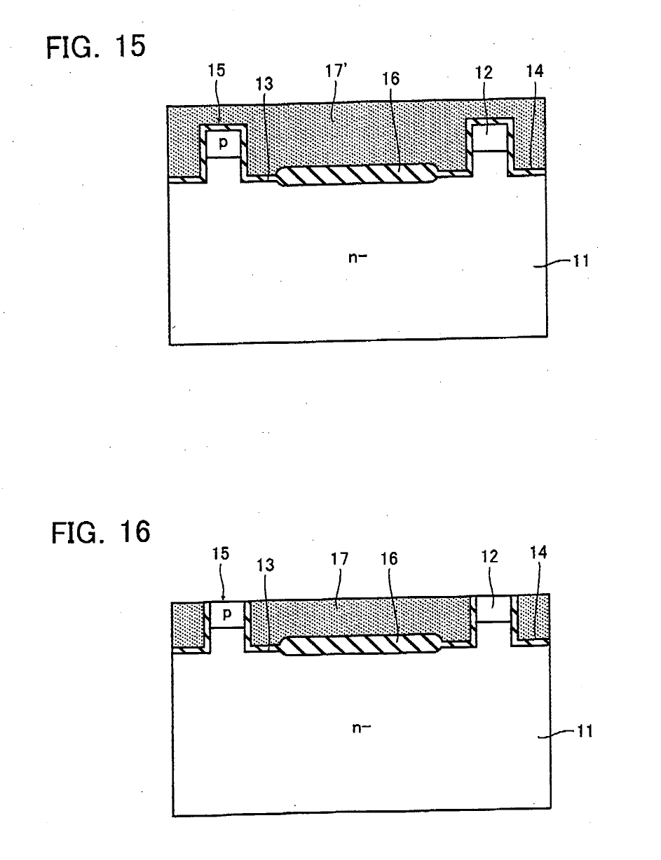

First, a p-type impurity such as boron is diffused into one surface of the high-resistance, n⁻-type base layer 11 as shown in FIG. 9 to form the p-type base layer 12 as shown in FIG. 10. Next, a trench 13 is etched with a width of about 1 μm through the p-type base layer 12 to the n⁻-type base layer 11, leaving a narrow silicon layer to form the mesa section 15, as shown in FIG. 11. Subsequently, after oxidation of the upper surface to form the gate oxide 14, a nitride film 14′ is deposited thereon as shown in FIG. 12. A RIE (reactive Ion Etching) or the like is then applied to remove the nitride film 14′, leaving the portions on the sidewalls of the trench 13 as shown in FIG. 13. The nitride film left as above is used as a mask to perform LOCOS (local oxidation of silicon) oxidation to thicken the oxide film on the bottom of the trench 13 as shown in FIG. 14. Subsequently, the nitride film 14′ is removed, and then a layer of donor- or acceptor-doped polysilicon 17′ is deposited over the entire surface including the trench 13 as shown in FIG. 15. Thereafter, the upper surface of the polysilicon 17′ is polished by CMP (Chemical Mechanical Polishing) or the like to planarize the surface until the upper surface of the p-type base layer 12 is exposed as shown in FIG. 16.

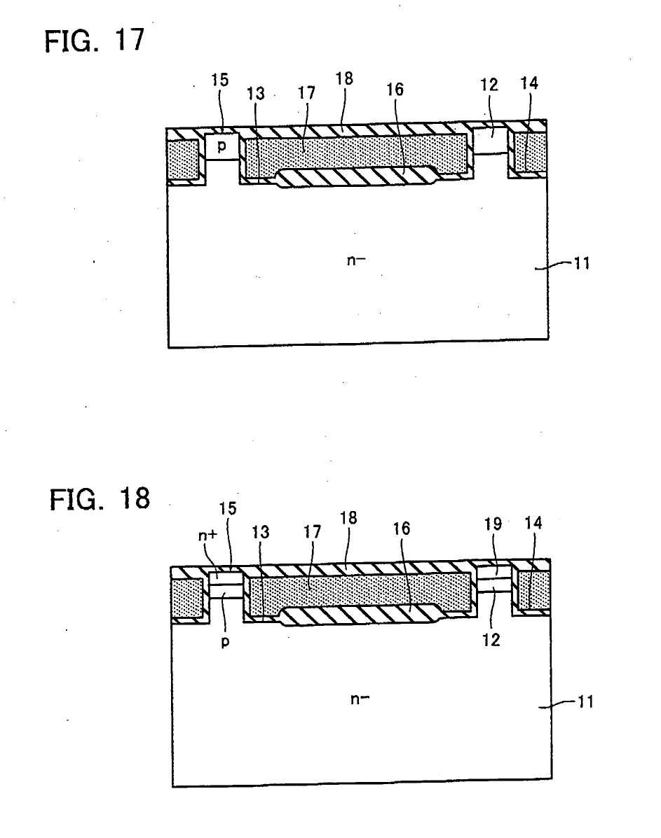

Next, the upper surface is oxidized to form the oxide film 18 as shown in FIG. 17. Then, a p-type impurity such as boron and an n-type impurity such as arsenic are sequentially implanted through high-acceleration ion implantation or the like and thermally diffused. As a result, the n⁺-type source layer 19 and the p⁺-type contact layer 20 are sequentially formed on the upper surface of the p-type base layer 12 as shown in FIG. 18. Subsequently, the upper surface of the oxide film 18 is polished to expose the upper surface of the mesa section 15 as shown in FIG. 19. Thereafter, the emitter electrode 21 is formed over the entire surface as shown in FIG. 2, then the lower surface of the wafer is removed by etching, and the upper surface is polished for planarization. Then, the n⁺-type buffer layer 22 and the p⁺-type emitter layer 23 are formed in this order through double ion implantation, and the collector electrode 24 is formed covering the p⁺-type emitter layer 23 to complete the device.

The present invention is not limited to the above-described embodiments.

The whole width of the mesa section 15 is designed to satisfy the above-described condition in the above embodiments though the effect of the present invention can be achieved if part of the width of the mesa section 15 is configured to satisfy the above-described condition.

What is claimed is:

1. A semiconductor device, comprising:
a first semiconductor layer of the first conduction type;
a second semiconductor layer of the second conduction type formed on one surface of said first semiconductor layer;
a gate electrode formed in a trench with an insulator interposed therebetween, said trench passing through said second semiconductor layer and reaching said first semiconductor layer;
a third semiconductor layer of the first conduction type formed on a surface of said second semiconductor layer between adjacent gate electrodes;
a first main electrode connected to said second and third semiconductor layers;
a fourth semiconductor layer of the second conduction type formed on the other surface of said first semiconductor layer; and
a second main electrode connected to said fourth semiconductor layer,
wherein said semiconductor layer between said adjacent gate electrodes has a width d ranging from 0.55 nm to 0.3 μm.

2. The semiconductor device according to claim 1, wherein said width d of said semiconductor layer is more than 30 nm.

3. The semiconductor device according to claim 1, wherein said width d of said semiconductor layer is less than 0.1 μm.

4. The semiconductor device according to claim 3, wherein said width d of said semiconductor layer is more than 30 nm.

5. The semiconductor device according to claim 1, further comprising a fifth semiconductor layer of the first conduction type provided between said fourth semiconductor layer and said first semiconductor layer, said fifth semiconductor layer having a higher impurity concentration than that of said first semiconductor layer.

6. The semiconductor device according to claim 5, wherein the dose of impurity into said fourth semiconductor layer ranges from 5×10¹² cm⁻² to 2×10¹⁴ cm⁻².

7. The semiconductor device according to claim 1, wherein said insulator located on the bottom of said trench comprises a LOCOS oxide film.

8. The semiconductor device according to claim 1, wherein said third semiconductor layer and a contact layer of the second conduction type are formed on said second semiconductor layer alternately In a direction orthogonal to the direction of arrangement of said adjacent gate electrodes.

9. A semiconductor device, comprising:
a first semiconductor layer of the first conduction type;
a second semiconductor layer of the second conduction type formed on one surface of said first semiconductor layer:
a gate electrode formed in a trench with an insulator interposed therebetween, said trench passing through said second semiconductor layer and reaching said first semiconductor layer;
a third semiconductor layer of the first conduction type formed on the a surface of said second semiconductor layer between adjacent gate electrodes;
a first main electrode connected to said second and third semiconductor layers;
a fourth semiconductor layer of the second conduction type formed on the other surface of said first semiconductor layer; and
a second main electrode connected to said fourth semiconductor layer,
wherein said semiconductor layer between adjacent gates has a width d, which satisfies the following relation:
0.55 nm≦d≦0.1·L·S/W+2λ
where L denotes a depth from an interface between said first semiconductor layer and said second semiconductor layer to the bottom of said trench; S an element repetition pitch; W a thickness of said first semiconductor layer; and λ a thickness of a channel.

10. A semiconductor device, comprising:
a first semiconductor layer of the first conduction type;
a second semiconductor layer of the second conduction type formed on one surface of said first semiconductor layer:
a gate electrode formed in a trench with an insulator interposed therebetween, said trench passing through said second semiconductor layer and reaching said first semiconductor layer;
a third semiconductor layer of the first conduction type formed on a surface of said second semiconductor layer between adjacent gate electrodes;
a first main electrode connected to said second and third semiconductor layers;
a fourth semiconductor layer of the second conduction type formed on the other surface of said first semiconductor layer: and
a second main electrode connected to said fourth semiconductor layer,
wherein said semiconductor layer between adjacent gates has a width d, which satisfies 2λ≦d≦0.3 μm (λ: a thickness of a channel).

11. The semiconductor device according to claim 8, wherein said width d satisfies 0.1 μm≦d≦0.3 μm.

12. The semiconductor device according to claim 10, further comprising a fifth semiconductor layer of the first conduction type provided between said fourth semiconductor layer and said first semiconductor layer, said fifth semiconductor layer having a higher impurity concentration than that of said first semiconductor layer.

13. The semiconductor device according to claim 12, wherein the dose of impurity into said fourth semiconductor layer ranges from 5×10¹² to 2×10¹⁴ cm⁻².

14. The semiconductor device according to claim 10, wherein said insulator located on the bottom of said trench comprises a LOCOS oxide film.

15. The semiconductor device according to claim 10, wherein said third semiconductor layer and a contact layer of the second conduction type are formed on said second semiconductor layer alternately in a direction orthogonal to the direction of arrangement of said adjacent gate electrodes.
